(19) United States
(12) Patent Application Publication
(10) Pub. No.: US 2016/0099030 A1
(43) Pub. Date: Apr. 7, 2016

(54) STROBE SIGNAL INTERVAL DETECTION CIRCUIT AND MEMORY SYSTEM INCLUDING THE SAME

(71) Applicant: SK hynix Inc., Icheon-si Gyeonggi-do (KR)

(72) Inventor: Hyeong Jun KO, Icheon-si Gyeonggi-do (KR)

(21) Appl. No.: 14/592,680

(22) Filed: Jan. 8, 2015

(30) Foreign Application Priority Data
Oct. 7, 2014 (KR) 10-2014-0134972

(51) Int. Cl. G11C 7/22

(52) U.S. Cl. CPC G11C 7/22

(57) ABSTRACT

A strobe signal interval detection circuit may include an oscillator configured to generate a periodic signal at a preset cycle determined through a delay time of a delay circuit. The delay time of the delay circuit may be configured by modeling a path traveled by a strobe signal being transmitted to a data latch. The strobe signal interval detection circuit may include a counter configured to count the periodic signal and generate strobe interval information.

### CROSS-REFERENCES TO RELATED APPLICATION

The present application claims priority under 35 U.S.C. §119(a) to Korean application number 10-2014-0134972, filed on Oct. 7, 2014, in the Korean Intellectual Property Office, which is incorporated herein by reference in its entirety.

### BACKGROUND

1. Technical Field

Various embodiments generally relate to a semiconductor circuit, and more particularly, to a strobe signal interval detection circuit and a memory system including the same.

2. Related Art

During a write operation of a semiconductor circuit including a semiconductor memory, the semiconductor circuit may receive data DQ from a memory controller. The data DQ received from the memory controller may be provided in accordance with a strobe signal DQS provided from the memory controller. The received data DQ may then be stored within the memory.

A delay time of a path through which the strobe signal DQS is provided to a latch for latching the data DQ through a delay circuit for a timing margin may be referred to as a strobe interval tDQS2DQ.

The strobe interval tDQ2DQ may be changed according to a PVT (Power, Voltage, Temperature) variation.

If the strobe interval tDQS2DQ is significantly changed, then an error may occur during a data write operation.

### SUMMARY

In an embodiment, a strobe signal interval detection circuit may include an oscillator configured to generate a periodic signal at a preset cycle determined through a delay time of a delay circuit, the delay time of the delay circuit configured by modeling a path traveled by a strobe signal being transmitted to a data latch. The strobe signal interval detection circuit may include a counter configured to count the periodic signal and generate strobe interval information.

In an embodiment, a memory system may include a semiconductor memory configured to store data according to a strobe signal, and generate strobe interval information by counting a periodic signal for a preset time, the periodic signal being generated at a cycle set through a delay time of a delay circuit. The delay time of the delay circuit configured by modeling a path traveled by the strobe signal being transmitted to a data latch. The memory system may include a memory controller configured to provide the data and the strobe signal to the semiconductor memory, and configured to adjust an output timing of the data or the strobe signal in response to the strobe interval information.

### BRIEF DESCRIPTION OF THE DRAWINGS

FIG. 1 is a circuit diagram illustrating a representation of a data latch-related configuration of a semiconductor memory according to an embodiment.

FIG. 2 is a block diagram of a representation of a strobe signal interval detection circuit according an embodiment.

FIG. 3 is a circuit diagram illustrating a representation of the configurations of a control unit illustrated in FIG. 2.

FIG. 4 is a circuit diagram illustrating a representation of the configurations of the driver illustrated in FIG. 2.

FIG. 5 is a circuit diagram illustrating a representation of the configurations of the overflow determination unit illustrated in FIG. 2.

FIGS. 6 and 7 are operation timing diagram representations of a strobe signal interval detection circuit according to an embodiment.

FIG. 8 is a block diagram of a representation of a memory system according to an embodiment.

### DETAILED DESCRIPTION

Hereinafter, a strobe signal interval detection circuit and a memory system including the same according to the present disclosure will be described below with reference to the accompanying drawings through various examples of embodiments.

Various embodiments may be directed to a strobe signal interval detection circuit capable of detecting a variation of a strobe interval and handing the varied strobe interval, and a memory system including the same.

During a write operation of a semiconductor memory, the semiconductor memory may receive data DQ from a memory controller according to a strobe signal DQS provided from the memory controller, and store the received data.

The memory controller may include a CPU (Central Processing Unit) or GPU (Graphics Processing Unit).

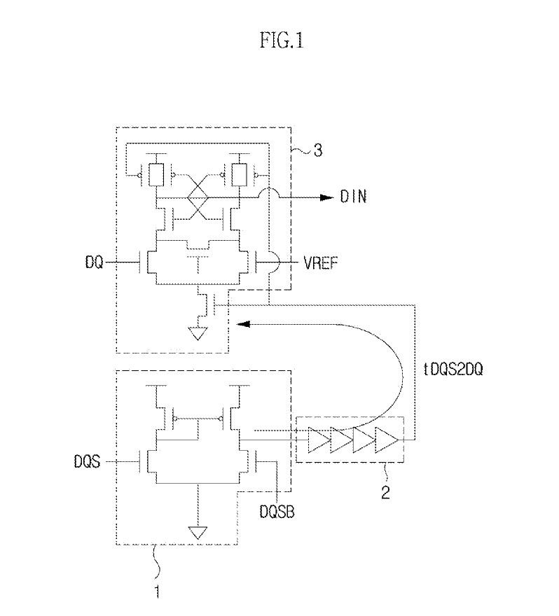

As illustrated FIG. 1, the semiconductor memory may receive a strobe signal DQS. The strobe signal DQS may be received through a buffer 1.

The strobe signal DQS may be delayed through a delay unit 2. The strobe signal DQS may be delayed by the delay unit 2 to match the timing margin for latching the data DQ. After the strobe signal DQS is delayed through the delay unit 2, the strobe signal DQS may then be provided to a data latch 3.

The data latch 3 may latch data DQ according to the delayed strobe signal DQS, and generate input data DIN.

A path may be defined as the path used to provide the strobe signal DQS through the delay unit 2 and to the data latch 3. A delay time of the path through which the strobe signal DQS is provided to the data latch 3 through the delay unit 2 may be referred to as a strobe interval tDQS2DQ. The delay time of the path traveled by the strobe signal DQS being provided to the data latch 3 through the delay unit 2 may be referred to as a strobe interval tDQS2DQ.

The data latch 3 may also be configured to receive a reference voltage VREF. The buffer 1 may also be configured to receive an inverse strobe signal DQSB.

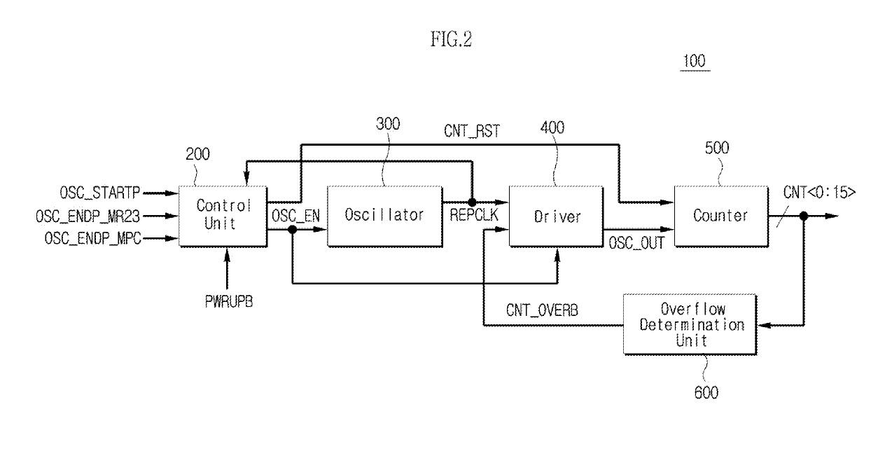

Referring to FIG. 2, the strobe signal interval detection circuit 100 according to an embodiment may include a control unit 200, an oscillator 300, and a driver 400. The strobe signal interval detection circuit 100 may include a counter 500 and an overflow determination unit 600.

The control unit 200 may be configured to generate an oscillation period signal OSC_EN for determining an activation time of the oscillator 300. The oscillation period signal OSC_EN may be generated by the control unit 200 in response to a start command OSC_STARTP, an end command OSC_ENDP_MPC, and an internal end command OSC_ENDP_MR23. In an embodiment, the oscillation period signal OSC_EN may be generated by the control unit 200 in response to a start command OSC_STARTP and an end command OSC_ENDP_MPC. In an embodiment, the oscillation period signal OSC_EN may be generated by the control unit 200 in response to a start command OSC_STARTP and an internal end command OSC_ENDP_MR23.

The control unit 200 may be configured to activate the oscillation period signal OSC_EN. The oscillation period signal OSC_EN may be activated by the control unit 200 in response to the start command OSC_STARTP.

The control unit 200 may be configured to deactivate the oscillation period signal OSC_EN. The oscillation period signal OSC_EN may be deactivated by the control unit 200 in response to the end command OSC_ENDP_MPC or the internal end command OSC_ENDP_MR23.

The start command OSC_STARTP and the end command OSC_ENDP_MPC may be received from outside the semiconductor memory, for example but not limited to, the memory controller.

The internal end command OSC_ENDP_MR23 may be generated on the basis of information stored in the semiconductor memory, for example but not limited to, a mode register set (MRS).

The internal end command OSC_ENDP_MR23 may be activated after an amount of time after the start command OSC_STARTP is inputted. The amount of time may be set on the basis of the information stored in the MRS.

The control unit 200 may be configured to generate a count reset signal CNT_RST. The count reset signal CNT_RST may be generated by the control unit 200 in response to the start command OSC_STARTP.

The oscillator 300 may be configured to generate a periodic signal REPCLK at a preset cycle during the activation period of the oscillation period signal OSC_EN.

The oscillator 300 may include a delay circuit for determining the preset cycle.

The delay circuit of the oscillator 300 may be configured by modeling the path traveled by the strobe signal DQS transmitted to the data latch 3.

The driver 400 may be configured to generate an output signal OSC_OUT. The output signal OSC_OUT may be generated by the driver 400 in response to the periodic signal REPCLK and an overflow detection signal CNT_OVERB.

The driver 400 may generate the output signal OSC_OUT by driving the periodic signal REPCLK. The output signal OSC_OUT may be generated by driving the periodic signal REPCLK with the driver 400 when the overflow detection signal CNT_OVERB is deactivated.

The driver 400 may block an input of the periodic signal REPCLK and latch the previous output signal OSC_OUT. The input of the periodic signal REPCLK may be blocked by the driver 400 and the previous output signal OSC_OUT may be latched when the overflow detection signal CNT_OVERB is activated.

The counter 500 may be configured to count the periodic signal REPCLK and generate strobe interval information CNT<0:15>.

The counter 500 may be configured to reset the strobe interval information CNT<0:15>. The strobe interval information CNT<0:15> may be reset by the counter 500 in response to a count reset signal CNT_RST.

The overflow determination unit 600 may be configured to detect an overflow of the strobe interval information CNT<0:15> and generate the overflow detection signal CNT_OVERB.

The overflow determination unit 600 may be configured to activate the overflow detection signal CNT_OVERB to a logic low value, when the strobe interval information CNT<0:15> has the maximum value, that is, all signal bits of the strobe interval information CNT<0:15> are at a logic high value.

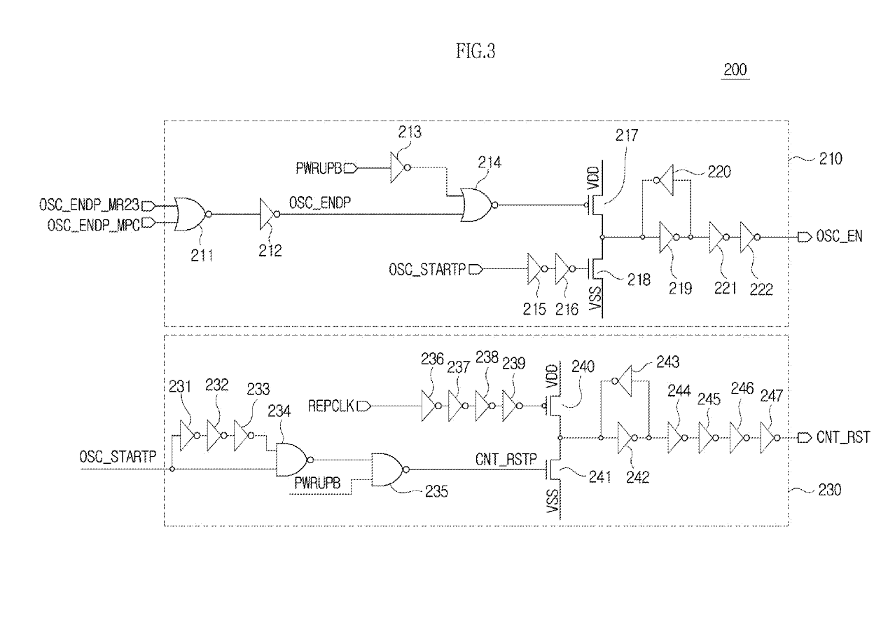

Referring to FIG. 3, the control unit 200 may include an oscillation period signal generator 210 and a counter reset signal generator 230.

The oscillation period signal generator 210 may be configured to generate the oscillation period signal OSC_EN. The oscillation period signal OSC_EN may be generated by the oscillation period signal generator 210 in response to the start command OSC_STARTP, the end command OSC_ENDP_MPC, the internal end command OSC_ENDP_MR23, and a power-up signal PWRUPB.

The oscillation period signal generator 210 may reset the oscillation period signal OSC_EN to a logic low value. The oscillation period signal OSC_EN may be reset to a logic low value by the oscillation period signal generator 210 in response to the power-up signal PWRUP.

The oscillation period signal generator 210 may activate the oscillation period signal OSC_EN to a logic high value. The oscillation period signal OSC_EN may be activated to the logic high value by the oscillation period signal generator 210 in response to the start command OSC_STARTP.

The oscillation period signal generator 210 may deactivate the oscillation period signal OSC_EN to a logic low value. The oscillation period signal OSC_EN may be deactivated to the logic low value by the oscillation period signal generator 210 in response to the end command OSC_ENDP_MPC or the internal end command OSC_ENDP_MR23.

The oscillation period signal generator 210 may include first to 12th logic gates 211 to 222.

The first logic gate 211 may be configured to perform a NOR operation on the end command OSC_ENDP_MPC and the internal end command OSC_ENDP_MR23.

The second logic gate 212 may be configured to invert an output of the first logic gate 211 and generate an output signal (i.e., internal signal OSC_ENDP).

The third logic gate 213 may be configured to invert the power-up signal PWRUPB.

The fourth logic gate 214 may be configured to perform a NOR operation on the output of the second logic gate 212 (i.e., internal signal OSC_ENDP) and an output of the third logic gate 213.

The fifth and sixth logic gates 215 and 216 may be configured to delay the start command OSC_STARTP.

The seventh logic gate 217 may be configured to output a power supply voltage VDD according to an output of the fourth logic gate 214.

The eighth logic gate 218 may be configured to output a ground voltage VSS according to the output of the sixth logic gate 216.

The ninth and tenth logic gates 219 and 220 may be configured to latch the output of the seventh logic gate 217 or the eighth logic gate 218.

The 11th and 12th logic gates 221 and 222 may be configured to delay an output of the ninth logic gate 219 and output the delayed signal as the oscillation period signal OSC_EN.

The count reset signal generator 230 may be configured to generate the count reset signal CNT_RST. The count reset signal CNT_RST may be generated by the count reset signal generator 230 in response to the start command OSC_STARTP, the power-up signal PWRUPB, and the periodic signal REPCLK.

The count reset signal generator 230 may activate the count reset signal CNT_RST to a logic high value. The count reset signal CNT_RST may be activated to the logic high value by the count reset signal generator 230 in response to the power-up signal PWRUPB.

The count reset signal generator 230 may activate the count reset signal CNT_RST to a logic high value. The count reset signal CNT_RST may be activated to the logic high value by the count reset signal generator 230 in response to the start command OSC_STARTP.

The count reset signal generator 230 may deactivate the count reset signal CNT_RST to a logic low value. The count reset signal CNT_RST may be deactivated to the logic low value by the count reset signal generator 230 in response to the periodic signal REPCLK.

The count reset signal generator 230 may include 13th to 29th logic gates 231 to 247.

The 13th to 16th logic gates 231 to 234 may be configured to generate a pulse signal in response to the start command OSC_STARTP.

The seventh logic gate 235 may be configured to perform a NAND operation on an output signal of the 16th logic gate 234 and the power-up signal PWRUPB.

The 18th to 21st logic gates 236 to 239 may be configured to delay the periodic signal REPCLK.

The 22nd logic gate 240 may be configured to output the power supply voltage VDD according to an output of the 21st logic gate 239.

The 23rd logic gate 241 may be configured to output the ground voltage VSS according to an output of the 17th logic gate 235.

The 24th and 25th logic gates 242 and 243 may be configured to latch the output of the 22nd logic gate 240 or the 23rd logic gate 241.

The 26th to 29th logic gates 244 and 247 may be configured to delay an output of the 24th logic gate 242 and generate the count reset signal CNT_RST.

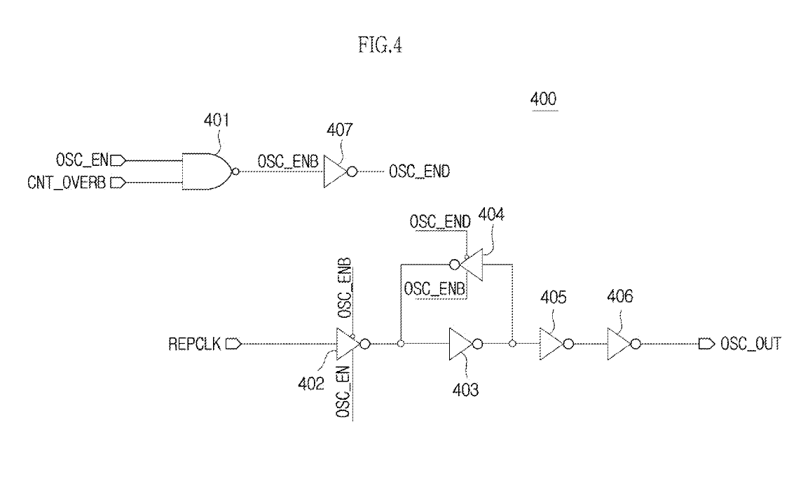

Referring to FIG. 4, the driver 400 may be configured to generate the output signal OSC_OUT. The output signal OSC_OUT may be outputted by the driver 400 in response to the oscillation period signal OSC_EN, the overflow detection signal CNT_OVERB, and the periodic signal REPCLK.

The driver 400 may include first to seventh logic gates 401 to 407.

The first logic gate 401 may be configured to perform a NAND operation on the oscillation period signal OSC_EN and the overflow detection signal CNT_OVERB and generate an inverted oscillation period signal OSC_ENB.

The first logic gate 401 may invert the oscillation period signal OSC_EN and generate the inverted oscillation period signal OSC_ENB, when the overflow detection signal CNT_OVERB is deactivated to a logic high value.

The first logic gate 401 may generate the inverted oscillation period signal OSC_ENB at a logic high value regardless of the oscillation period signal OSC_EN, when the overflow detection signal CNT_OVERB is activated to a logic low value.

The second logic gate 407 may be configured to invert the inverted oscillation period signal OSC_ENB and generate the delayed oscillation period signal OSC_END.

The third logic gate 402 may be configured to invert the periodic signal REPCLK in response to the oscillation period signal OSC_EN and the inverted oscillation period signal OSC_ENB.

The fourth logic gate 403 may be configured to invert an output of the third logic gate 402.

The fifth logic gate 404 may be configured to latch an output of the fourth logic gate 403 in response to the inverted oscillation period signal OSC_ENB and the delayed oscillation period signal OSC_END.

The sixth and seventh logic gates 405 and 406 may be configured to delay the output of the fourth logic gate 403 and generate the output signal OSC_OUT.

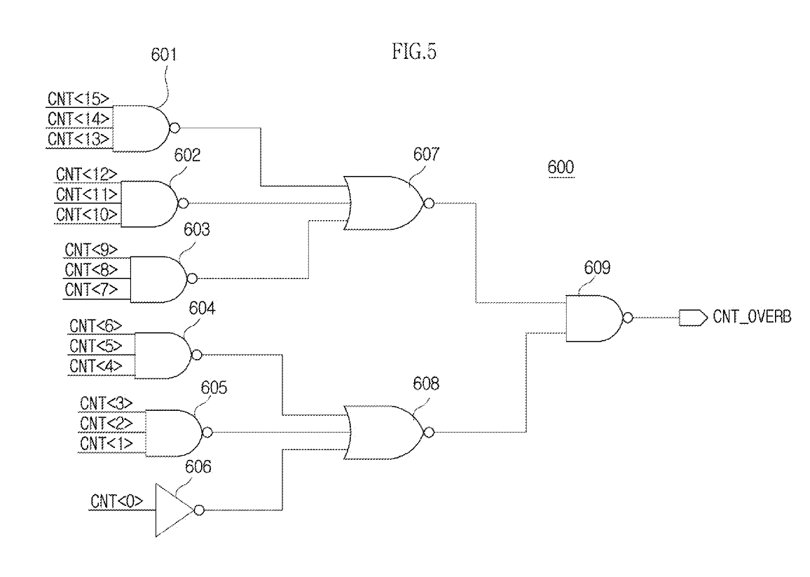

Referring to FIG. 5, the overflow determination unit 600 may be configured to activate the overflow detection signal CNT_OVERB to a logic low value, when the strobe interval information CNT<0:15> has the maximum value, that is, all signal bits of the strobe interval information CNT<0:15> are at a logic high value.

The overflow determination unit 600 may include first to ninth logic gates 601 to 609.

The first logic gate 601 may be configured to perform a NAND operation on signal bits CNT<15:13> of the strobe interval information CNT<0:15>.

The second logic gate 602 may be configured to perform a NAND operation on signal bits CNT<12:10> of the strobe interval information CNT<0:15>.

The third logic gate 603 may be configured to perform a NAND operation on signal bits CNT<9:7> of the strobe interval information CNT<0:15>.

The fourth logic gate 604 may be configured to perform a NAND operation on signal bits CNT<6:4> of the strobe interval information CNT<0:15>.

The fifth logic gate 605 may be configured to perform a NAND operation on signal bits CNT<3:1> of the strobe interval information CNT<0:15>.

The sixth logic gate 606 may be configured to invert a signal bit CNT<0> of the strobe interval information CNT<0:15>.

The seventh logic gate 607 may be configured to perform a NOR operation on outputs of the first to third logic gates 601 to 603.

The seventh logic gate 608 may be configured to perform a NOR operation on outputs of the first to third logic gates 604 to 606.

The ninth logic gate 609 may be configured to perform a NAND operation on outputs of the seventh and eighth logic gates 607 and 608 and output the operation result as the overflow signal CNT_OVERB.

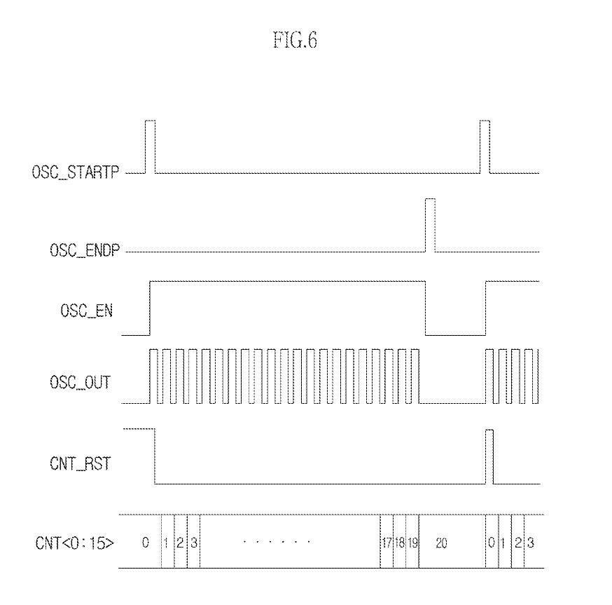

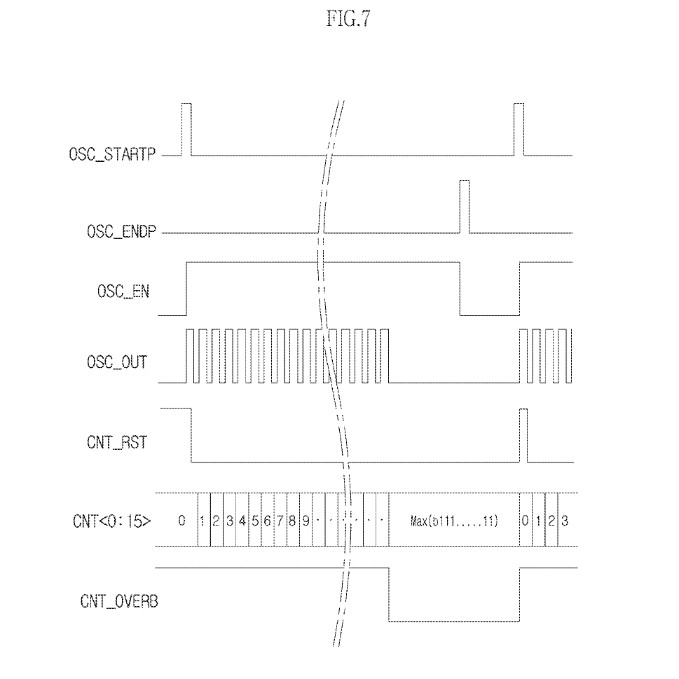

The operation of the strobe signal interval detection circuit 100 according to an embodiment will be described below with reference to FIGS. 6 and 7.

First, the examples in which an overflow of the strobe interval information CNT<0:15> does not occur will be described with reference to FIG. 6.

According to the start command OSC_STARTP provided from, for example, the memory controller, the oscillation period signal OSC_EN may be activated.

During the activation period of the oscillation period signal OSC_EN, the periodic signal REPCLK generated from the oscillator 300 may be generated as an output signal OSC_OUT through the driver 400.

At this time, according to the start command OSC_STARTP, the count reset signal CNT_RST may be activated to a logic high value to reset the strobe interval information CNT<0:15>. Then, the count reset signal CNT_RST may be deactivated to a logic low value according to the periodic signal REPCLK.

After the reset signal CNT_RST is deactivated to a logic low value, the counter 500 may count the output signal OSC_OUT and increase the strobe interval information CNT<0:15>.

According to the internal signal OSC_ENDP generated through the end command OSC_ENDP_MPC or the internal end command OSC_ENDP_MR23 provided from, for example, the memory controller, the oscillation period signal OSC_EN may be deactivated.

The counter 500 may be configured to latch the value of the strobe interval information CNT<0:15> (for example, 20) which is generated by counting the output signal OSC_OUT until the oscillation period signal OSC_EN is deactivated.

Since the value of the strobe interval information CNT<0:15> did not reach the maximum value, the overflow detection signal CNT_OVERB (referring to FIG. 5) may be maintained in a deactivated state (logic high value).

Next, the examples in which an overflow of the strobe interval information CNT<0:15> occurs will be described below with reference to FIG. 7.

According to the start command OSC_STARTP provided from the memory controller, the oscillation period signal OSC_EN may be activated.

During the activation period of the oscillation period signal OSC_EN, the periodic signal REPCLK generated from the oscillator 300 may be generated as an output signal OSC_OUT through the driver 400.

At this time, according to the start command OSC_STARTP, the count reset signal CNT_RST may be activated to a logic high value to reset the strobe interval information CNT<0:15>. Then, the count reset signal CNT_RST may be deactivated to a logic low value according to the periodic signal REPCLK.

After the reset signal CNT_RST is deactivated to a logic low value, the counter 500 may count the output signal OSC_OUT and increase the strobe interval information CNT<0:15>.

Since the strobe interval information CNT<0:15> reaches the maximum value Max (i.e., b111 . . . 11), the overflow detection signal CNT_OVERB may be activated to a logic low value.

As the overflow detection signal CNT_OVERB is activated to a logic low value, the driver 400 may block an input of the periodic signal REPCLK and maintain the output signal OSC_OUT at a logic low value.

Since the output signal OSC_OUT is not generated any more, the counter 500 may maintain the strobe interval information CNT<0:15> at the maximum value.

According to the internal signal OSC_ENDP which is generated through the end command OSC_ENDP_MPC or the internal end command OSC_ENDP_MR23 provided from the memory controller, the oscillation period signal OSC_EN may be deactivated.

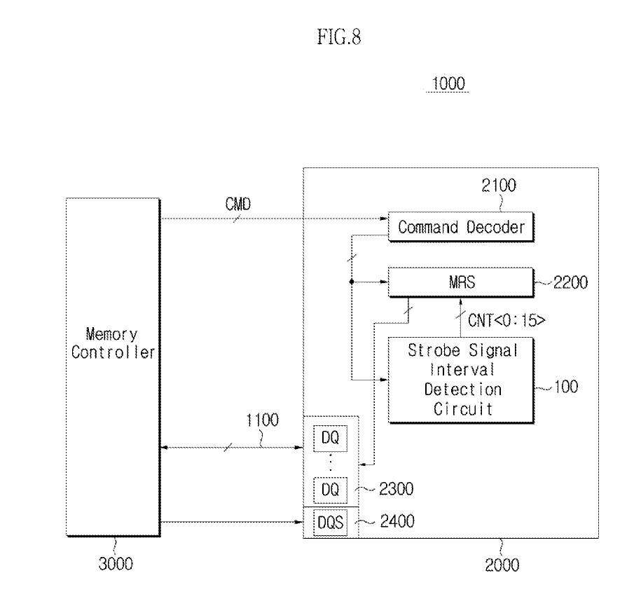

Referring to FIG. 8, a memory system 1000 according to an embodiment may include a semiconductor memory 2000 and a memory controller 3000.

The semiconductor memory 2000 and the memory controller 3000 may be coupled through a data bus 1100.

The semiconductor memory 2000 may be configured to store data DQ according to a strobe signal DQS, and generate strobe interval information CNT<0:15> by counting a periodic signal REPCLK for a predetermined time. The periodic signal REPCLK may be generated at a cycle which is set through a delay time of a delay circuit configured by modeling a path through which the strobe signal DQS is transmitted to a data latch (i.e., see FIG. 1).

The semiconductor memory 2000 may include a command decoder 2100, a mode register set (MRS) 2200, a strobe signal interval detection circuit 100, a first pad unit 2300, and a second pad unit 2400.

The strobe signal interval detection circuit 100 may use the configuration of FIG. 2 and the embodiments associated with FIGS. 2-7.

The first pad unit 2300 may include a plurality of data pads DQ.

The second pad unit 2400 may include a strobe signal pad DQS.

The command decoder 2100 may be configured to decode a command CMD provided from the memory controller 3000, and generate various commands, that is for example, a start command OSC_STARTP, an end command OSC_ENDP_MPC, and an MRS read command.

The MRS 2200 may be configured to store the strobe interval information CNT<0:15> generated by the strobe signal interval detection circuit 100 (i.e., see FIG. 2).

The MRS 2200 may be configured to transmit the strobe interval information CNT<0:15> to the memory controller 3000 through the first pad unit 2300 and a data bus 1100, in response to the MRS read command.

The memory controller 3000 may be configured to provide the data DQ and the strobe signal DQS to the semiconductor memory 2000, determine a strobe interval tDQS2DQ based on the strobe interval information CNT<0:15>, and adjust an output timing of the data DQ or the strobe signal DQS.

The memory controller 3000 may include a CPU or GPU.

The operation of the memory system 1000 according to an embodiment will be described below.

The memory controller 3000 may be configured to control the command CMD and provide the start command OSC_STARTP and the end command OSC_ENDP_MPC to the semiconductor memory 2000 at a preset timing.

The strobe signal interval detection circuit 100 of the semiconductor memory 2000 may generate the strobe interval information CNT<0:15> and store the generated information in the MRS 2200, according to the start command OSC_STARTP and the end command OSC_ENDP_MPC or the internal end command OSC_ENDP_MR23.

The memory controller 3000 may control the command CMD and provide the MRS read command to the semiconductor memory 2000.

The semiconductor memory 2000 may transmit the strobe interval information CNT<0:15> stored in the MRS 2200 to the memory controller 3000 through the first pad unit 2300 and the data bus 1100, in response to the MRS read command.

The memory controller 3000 may receive the strobe interval information CNT<0:15> through the data bus 1100, determine the strobe interval tDQS2DQ based on the received strobe interval information CNT<0:15>, and adjust the output timing of the data DQ or the strobe signal DQS.

When the strobe interval tDQS2DQ is larger than a preset reference value, the memory controller 3000 may increase the delay time of the output path for the data DQ, and delay the output timing of the data DQ.

When the strobe interval tDQS2DQ is smaller than the preset reference value, the memory controller 3000 may decrease the delay time of the output path for the data DQ, and advance the output timing of the data DQ.

When the strobe interval tDQS2DQ is larger than the preset reference value, the memory controller 3000 may decrease the delay time of the output path for the strobe signal DQS, and advance the output timing of the strobe signal DQS.

When the strobe interval tDQS2DQ is smaller than the preset reference value, the memory controller 3000 may increase the delay time of the output path for the strobe signal DQS, and delay the output timing of the strobe signal DQS.

As described above, the memory controller 3000 may compensate for a variation of the strobe interval tDQS2DQ by adjusting the output timing of the data DQ or strobe signal DQS, thereby improving the reliability of the data write operation of the memory system 1000.

While various embodiments have been described above, it will be understood to those skilled in the art that the embodiments described are by way of example only. Accordingly, the semiconductor circuit described herein should not be limited based on the described embodiments.

What is claimed is:

1. A strobe signal interval detection circuit comprising:
an oscillator configured to generate a periodic signal at a preset cycle determined through a delay time of a delay circuit, the delay time of the delay circuit configured by modeling a path traveled by a strobe signal being transmitted to a data latch; and
a counter configured to count the periodic signal and generate strobe interval information.

2. The strobe signal interval detection circuit according to claim 1, further comprising:
a control unit configured to generate an oscillation period signal for determining an activation time of the oscillator,
wherein the control unit is configured to generate the oscillation period signal in response to a start command and an end command.

3. The strobe signal interval detection circuit according to claim 1, further comprising:
a control unit configured to generate an oscillation period signal for determining an activation time of the oscillator,
wherein the control unit is configured to generate the oscillation period signal in response to a start command and an internal end command.

4. The strobe signal interval detection circuit according to claim 2, wherein the control unit is configured to generate a count rest signal for resetting the value of the strobe interval information,
wherein the control unit is configured to generate the count rest signal in response to the start command.

5. The strobe signal interval detection circuit according to claim 1, further comprising:
an overflow determination unit configured to generate an overflow detection signal by detecting an overflow of the strobe interval information.

6. The strobe signal interval detection circuit according to claim 5, further comprising:
a driver configured to control the reception of the periodic signal by the counter, in response to the overflow detection signal.

7. A memory system comprising:
a semiconductor memory configured to store data according to a strobe signal, and generate strobe interval information by counting a periodic signal for a preset time, the periodic signal being generated at a cycle set through a delay time of a delay circuit, the delay time of the delay circuit is configured by modeling a path traveled by the strobe signal being transmitted to a data latch; and
a memory controller configured to provide the data and the strobe signal to the semiconductor memory, and configured to adjust an output timing of the data or the strobe signal in response to the strobe interval information.

8. The memory system according to claim 7, wherein the memory controller is configured to provide a start command and an end command to the semiconductor memory to control the preset time.

9. The memory system according to claim 7, wherein the semiconductor memory is configured to store the strobe interval information in a mode register set (MRS).

10. The memory system according to claim 7, wherein the memory controller is configured to receive the strobe interval information from the semiconductor memory through a data bus.

11. The memory system according to claim 10, wherein the memory controller is configured to provide an MRS read command to the semiconductor memory and control the semiconductor memory to provide the strobe interval information to the memory controller through the data bus.

12. The memory system according to claim 7, wherein the semiconductor memory comprises:
a strobe signal interval detection circuit configured to generate the strobe interval information;
an MRS configured to store the strobe interval information; and
a data input/output unit configured to transmit the strobe interval information to the memory controller through a data bus.

13. The memory system according to claim 12, wherein the strobe signal interval detection circuit comprises:
an oscillator configured to generate the periodic signal; and
a counter configured to count the periodic signal and generate the strobe interval information.

14. The memory system according to claim 13, wherein the strobe signal interval detection circuit further comprises:
a control unit configured to generate an oscillation period signal for determining an activation time of the oscillator,
wherein the control unit is configured to generate the oscillation period signal in response to a start command and an end command.

15. The memory system according to claim 14, wherein the control unit is configured to generate the oscillation period signal in response to the start command and an internal end command.

16. The memory system according to claim 15,
wherein the internal end command is generated on the basis of the strobe interval information stored in the MRS, and
wherein the end command is received by the control unit from the memory controller.

17. The memory system according to claim 14, wherein the control unit is configured to generate a count reset signal for resetting the value of the strobe interval information,
wherein the control unit is configured to generate the count reset signal in response to the start command.

18. The memory system according to claim 13, wherein the strobe signal interval detection circuit further comprises:
an overflow determination unit configured to detect an overflow of the strobe interval information and generate an overflow detection signal.

19. The memory system according to claim 18, wherein the strobe signal interval detection circuit further comprises:
a driver configured to control the reception of the periodic signal by the counter, in response to the overflow detection signal.

20. The memory system according to claim 19, wherein the reception of the periodic signal by the counter is blocked by the driver when the strobe interval information reaches a maximum value.
